(19) United States
(12) Patent Application Publication
(10) Pub. No.: US 2014/0354345 A1
(43) Pub. Date: Dec. 4, 2014

(54) SWITCH CONTROL CIRCUIT, SWITCHING POWER SUPPLY, AND ELECTRONIC APPARATUS

(71) Applicant: Rohm Co., Ltd., Kyoto (JP)

(72) Inventors: Kei Nagao, Kyoto (JP); Masaki Omi, Kyoto (JP)

(73) Assignee: Rohm Co., Ltd., Kyoto (JP)

(21) Appl. No.: 14/290,048

(22) Filed: May 29, 2014

(30) Foreign Application Priority Data
May 30, 2013 (JP) 2013114097

(51) Int. Cl. H03K 17/16; H03K 3/013

(52) U.S. Cl. CPC H03K 17/162; H03K 3/013
USPC 327/380

(57) ABSTRACT

A switch control circuit that includes a control unit configured to generate a control signal; a switch driving unit configured to drive a switch element based on the control signal; and a slew rate adjusting unit configured to control the switch driving unit to change a slew rate of the switch element periodically in a predetermined change pattern.

### CROSS-REFERENCE TO RELATED APPLICATIONS

This application is based upon and claims the benefit of priority from Japanese Patent Application No. 2013-114097, filed on May, 30, 2013, the entire contents of which are incorporated herein by reference.

### TECHNICAL FIELD

The present disclosure relates to a switch control circuit.

### BACKGROUND

FIG. 9 illustrates a slew rate of an output transistor. To increase the efficiency of a switching power supply, a slew rate of an output transistor may be set high to reduce a rising time tᵣ and a falling time t_{f} of a switch voltage V_{sw}. In contrast, to reduce an amount of electromagnetic interference (EMI) noise that is caused by operating the switching power supply, the slew rate of the output transistor may be set low to change the switch voltage V_{sw} slowly.

As such, a trade-off between the efficiency and the amount of noise of the switching power supply exists. Thus, optimizing a balance between the efficiency and the amount of noise may be desirable for each mounted set.

### SUMMARY

The present disclosure provides some embodiments of a switch control circuit that are capable of optimizing a balance between efficiency and the amount of noise for each mounted set, a switching power supply including the switch control circuit, and an electronic apparatus including the switching power supply.

According to one embodiment of the present disclosure, a switch control circuit includes a control unit configured to generate a control signal; a switch driving unit configured to drive a switch element based on the control signal; and a slew rate adjusting unit configured to control the switch driving unit to change a slew rate of the switch element periodically in a predetermined change pattern.

In one embodiment, the slew rate adjusting unit may control the switch driving unit to increase and decrease the slew rate of the switch element between a maximum candidate value and a minimum candidate value in the change pattern.

In one embodiment, the slew rate adjusting unit may control the switch driving unit to change the slew rate of the switch element every period of the control signal.

In one embodiment, the switch control circuit may further include an interface unit configured to exchange a signal with an external unit; and a register configured to store a plurality of register values that are inputted through the interface unit. In this embodiment, the slew rate adjusting unit may switch the change pattern based on a register value associated with change pattern setting.

In one embodiment, the change pattern may include setting the slew rate of the switch element to be a fixed value.

In one embodiment, the fixed value may be associated with a register value associated with slew rate adjustment.

In one embodiment, the switch driving unit may include a plurality of unit drivers connected in parallel, and the slew rate adjusting unit may change periodically a number of unit drivers being operated simultaneously among the plurality of unit drivers.

In one embodiment, the plurality of unit drivers may be formed by transistors having the same size.

According to another embodiment of the present disclosure, a switching power supply includes the above switch control circuit; and an output stage configured to generate an output voltage from an input voltage based on control by a switch element according to the switch control circuit.

According to still another embodiment of the present disclosure, an electronic apparatus includes the above switching power control circuit; and a load which is supplied with an output voltage from a switching power supply.

### BRIEF DESCRIPTION OF THE DRAWINGS

FIG. 1 illustrates a switching power supply according to a first embodiment of the present disclosure.

FIG. 2 illustrates an example of adjusting a slew rate.

FIG. 3 illustrates a configuration example of a unit driver.

FIG. 4 illustrates a state in which a through current is generated between unit drivers having different sizes.

FIG. 5 illustrates a switching power supply according to a second embodiment of the present disclosure.

FIG. 6 illustrates examples of a slew-rate adjustment operation based on a register value SWSRT.

FIG. 7 illustrates examples of automatic slew-rate switching operations based on the register value SWCHG.

FIG. 8 illustrates an external appearance of a mobile phone.

FIG. 9 illustrates a slew rate of an output transistor.

### DETAILED DESCRIPTION

### Switching Power Supply (First Embodiment)

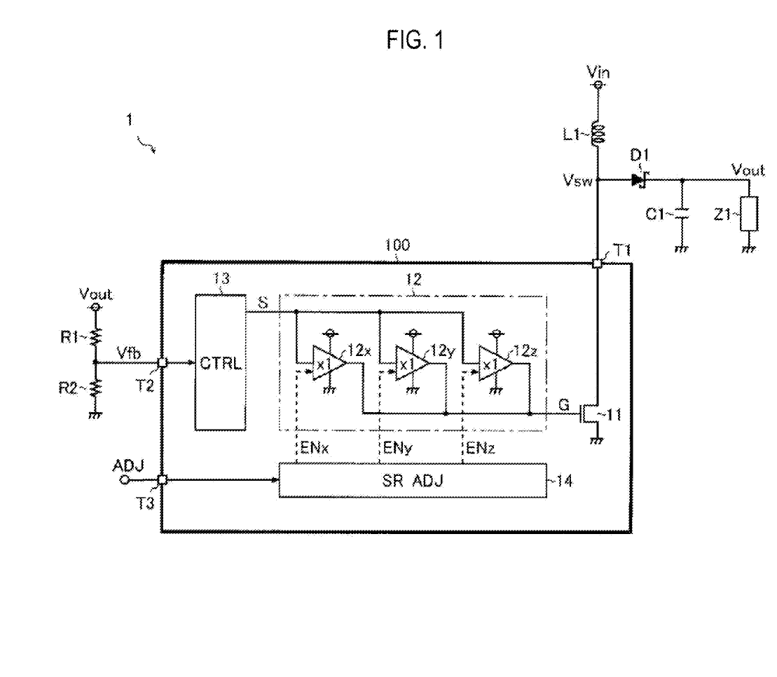

FIG. 1 illustrates a switching power supply according to a first embodiment of the present disclosure. A switching power supply 1 in this embodiment, which may be a boost switching regulator, includes a switch control IC (Integrated Circuit) 100 and discrete elements which are configured to form an output stage connected to the switch control IC 100. Such elements include an inductor L₁, a Schottky barrier diode D₁, a capacitor C₁, and resistors R₁ and R₂.

A first terminal of the inductor L₁ is connected to an input terminal of an input voltage Vᵢₙ, outside the switch control IC 100. A second terminal of the inductor L₁ is connected to a switch terminal T₁ of the switch control IC 100 (which is a terminal for applying a switch voltage V_{sw}) and an anode of the Schottky barrier diode D₁. A cathode of the Schottky barrier diode D₁ is connected to a terminal for applying an output voltage Vₒᵤₜ. The capacitor C₁ is connected between the terminal for applying the output voltage Vₒᵤₜ and a ground terminal The resistors R₁ and R₂ are connected in series between the terminal for applying the output voltage Vₒᵤₜ and the ground terminal A connection node between the resistor R₁ and the resistor R₂ is connected to a feedback terminal T₂ of the switch control IC 100 (which is a terminal for applying a feedback voltage V_{fb}). A load Z₁ is connected between the terminal for applying the output voltage Vₒᵤₜ and the ground terminal

The switch control IC 100, which may be a semiconductor IC device obtained by integrating a switch control circuit into a semiconductor chip, includes an output transistor 11, a switch driving unit 12, a control unit 13, and a slew rate adjusting unit 14. Additionally, the switch control IC 100 may include any suitable circuits such as an abnormality protection circuit, and the like.

The output transistor 11 is an N-channel type MOSFET (Metal Oxide Semiconductor Field Effect Transistor). A drain of the output transistor 11 is connected to the switch terminal T₁. A source of the output transistor 11 is connected to the ground terminal. A gate of the output transistor 11 is connected to an output terminal of the switch driving unit 12.

The switch driving unit 12 is configured to generate a gate signal G, which is obtained by increasing a current capacity of an ON/OFF control signal S inputted from the control unit 13, and provide the gate signal G to the gate of the output transistor 11. The switch driving unit 12 includes a plurality of unit drivers 12ₓ, 12_{y}, and 12_{z}. The unit drivers 12ₓ to 12_{z} are connected in parallel between a signal output terminal of the control unit 13 and the gate of the output transistor 11. Operations of the unit drivers 12x to 12z are controlled, respectively, based on enable signals ENₓ to EN_{z} that are inputted from the slew rate adjusting unit 14. The unit drivers 12ₓ to 12_{z} may include transistors having the same size.

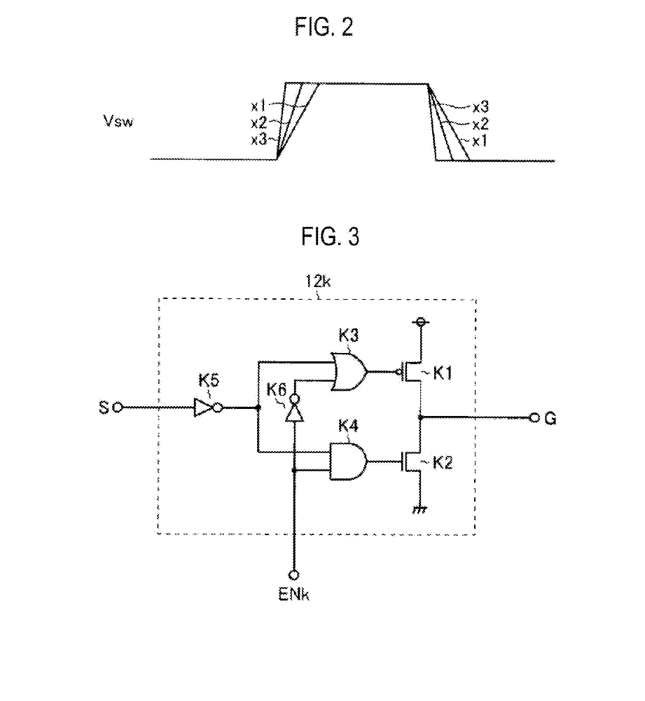

In the above configuration, the operations of any of the unit drivers 12ₓ to 12_{z} may be switched such that the current capacity of the switch driving unit 12 (and the slew rate of the output transistor 11) is switched between three states (i.e., “×1,” “×2,” and “×3”) (see FIG. 2). Specifically, the slew rate is “×1” when one of the unit drivers 12ₓ to 12, is operated, “×2” when two of the unit drivers 12ₓ to 12_{z} are operated simultaneously, and “×3” when all (i.e., three) of the unit drivers 12ₓ to 12_{z} are operated simultaneously.

Although FIG. 1 illustrates the switch driving unit 12 as including the three unit drivers 12ₓ to 12_{z}, the switch driving unit 12 may include any suitable number (e.g., four or more) of unit drivers.

According to an output feedback control based on the feedback voltage V_{fb}, the control unit 13 generates the ON/OFF control signal S for the output transistor 11 at a predetermined switching frequency such that a desired output voltage Vₒᵤₜ is generated from the input voltage Vᵢₙ. Any suitable techniques (e.g., well-known techniques in the art) may be used for the method of the output feedback control in the control unit 13, and thus, detailed explanations thereof are omitted.

The slew rate adjusting unit 14 generates the enable signal ENₓ to EN_{z} for the unit drivers 12ₓ to 12_{z}, respectively, in response to a slew rate adjustment signal ADJ that is inputted from the outside of the switch control IC 100 (i.e., an external unit). A high level signal may be assigned as the enable signals ENₓ to EN_{z} to operate the corresponding unit drivers 12ₓ to 12_{z}, respectively, while a low level signal may be assigned as the enable signals ENₓ to EN_{z} to stop the operations of the corresponding unit drivers 12ₓ to 12_{z}, respectively.

The operations (e.g., DC/DC conversion operation) of the switching power supply 1 configured as above are described below. When the output transistor 11 is turned on, a switch current flows through the inductor L₁ toward the ground terminal via the output transistor 11 while storing electric energy in the inductor L₁. In this case, since a voltage potential of the switch terminal T₁ is lowered down to near a ground potential via the output transistor 11, the Schottky barrier diode D₁ is backward biased, and thus, no current flows from the capacitor C₁ toward the output transistor 11. On the other hand, when the output transistor 11 is turned off, the electric energy stored in the inductor L₁ is released by a counter electromotive voltage that is generated in the inductor L₁. In this case, since the Schottky barrier diode D₁ is forward biased, a current flows through the Schottky barrier diode D₁, and then flows from the terminal for applying the output voltage Vₒᵤₜ into the load Z₁, and into the ground terminal via the capacitor C₁ while charging the capacitor C₁. By repeating the above operations, the output voltage Vₒᵤₜ which is obtained by boosting the input voltage Vᵢₙ is supplied to the load Z₁.

As such, the switch control IC 100 functions as an element of the boost switching regulator which boosts the input voltage Vᵢₙ and generates a desired output voltage Vₒᵤₜ by driving the inductor L₁ as an energy storage element, based on the ON/OFF control of the output transistor 11.

In addition, the switching power supply 1 of the first embodiment may properly vary the current capacity (i.e., ability of driving) of the switch driving unit 12 based on the control of the slew rate adjustment signal ADJ. Accordingly, without requiring a change in design of the switch driving unit 12 (further, a change in design of the switch control IC 100) and a change in design of a PCB (Printed Circuit Board) (e.g., addition of a snubber circuit), a balance between an efficiency and an amount of noise of the switching power supply 1 can be optimized for each mounted set.

FIG. 3 illustrates a configuration example of a unit driver 12ₖ (k=x, y, or z). The unit driver 12ₖ includes a P-channel type MOSFET K₁, an N-channel type MOSFET K₂, an OR gate K₃, an AND gate K₄, and NOT gates K₅ and K₆.

A source of the transistor K₁ is connected to a terminal for applying a supply voltage. Drains of the transistors K₁ and K₂ are connected to a terminal for applying a gate signal G. A source of the transistor K₂ is connected to a ground terminal A gate of the transistor K₁ is connected to an output terminal of the OR gate K₃. A gate of the transistor K₂ is connected to an output terminal of the AND gate K₄. A first input terminal of the OR gate K₃ and a first input terminal of the AND gate K₄ are connected to an output terminal of the NOT gate K₅. An input terminal of the NOT gate K5 is connected to a terminal for applying the ON/OFF control signal S. A second input terminal of the OR gate K₃ is connected to an output terminal of the NOT gate K₆. A second input terminal of the AND gate K₄ and an input terminal of the NOT gate K₆ are connected to a terminal for applying an enable signal ENₖ.

When the enable signal ENₖ which is inputted to the unit driver 12ₖ is of a high level (i.e., a logic level to enable an operation), the OR gate K₃ and the AND gate K₄ slew-output the ON/OFF control signal S that is logically inverted by the NOT gate K₅. Accordingly, when the ON/OFF control signal S is of a high level, the transistor K₁ is turned on and the transistor K2 is turned off, and thus, the gate signal G becomes a high level. In contrast, when the ON/OFF control signal S is of a low level, the transistor K₁ is turned off and the transistor K₂ is turned on, and thus, the gate signal G becomes a low level.

On the other hand, when the enable signal ENₖ which is inputted to the unit driver 12ₖ is of a low level (i.e., a logic level to disable an operation), the OR gate K₃ outputs a high level signal and the AND gate K₄ outputs a low level signal, regardless of the ON/OFF control signal S. Thus, since both the transistors K₁ and K₂ are turned off, the gate signal G falls into a high impedance state.

Thus, the unit driver 12ₖ as configured above can implement an enable control with a simple circuit configuration.

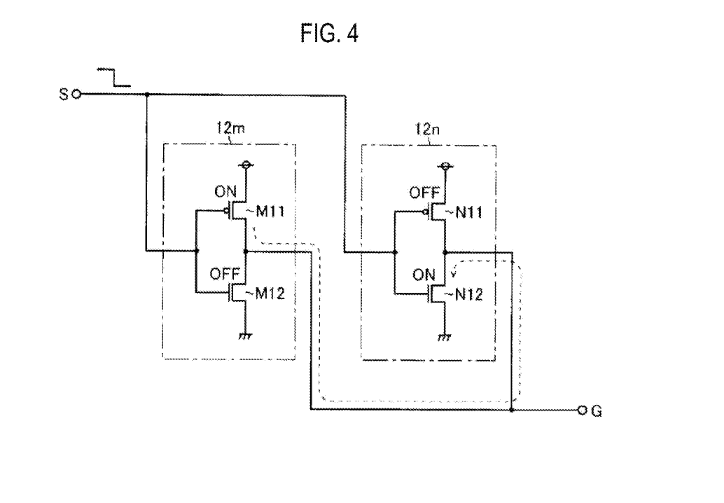

Next, the reason why the transistors forming the unit drivers 12ₓ to 12_{z} may have the same size is described below in detail. FIG. 4 illustrates a state in which a through current is generated between unit drivers having different sizes. Here, it is assumed that transistors M₁₁ and M₁₂ forming a unit driver 12ₘ are smaller in size than transistors N₁₁ and N₁₂ forming a unit driver 12ₙ and are more quickly switched between ON and OFF states in response to the ON/OFF control signal S than the transistors N₁₁ and N₁₂. It is also assumed that both the unit drivers 12ₘ and 12ₙ are in an enable state.

For example, when the ON/OFF control signal S is switched from a high level to a low level, the transistors M₁₁ and M₁₂ forming the unit driver 12ₘ are switched from an OFF state to an ON state and from an ON state to an OFF state, respectively, without delay. On the other hand, the transistors N₁₁ and N₁₂ forming the unit driver 12ₙ are switched from an OFF state to an ON state and from an ON state to an OFF state, respectively, later than the transistors M₁₁ and M₁₂. If such a period of time exists in which both the transistor M₁₁ and the transistor N₁₂ are in the ON state simultaneously due to the difference between the ON/OFF switching timings, an excessive through current may flow through a path from an input terminal of a supply voltage to a ground terminal via the transistors M₁₁ and N₁₂, which may result in destruction, fuming, fire, and so on of elements.

In contrast, since the transistors forming the unit drivers 12ₓ to 12_{z} in the switching power supply 1 according to the first embodiment have the same size, there is no difference between ON/OFF switching timings, which may prevent a through current.

### Switching Power Supply (Second Embodiment)

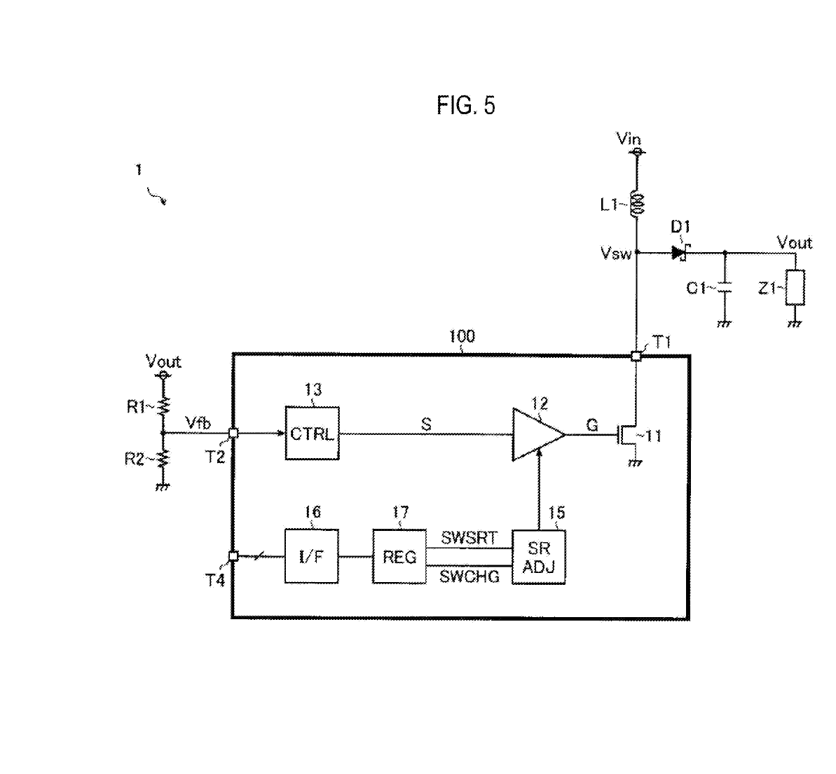

FIG. 5 illustrates a switching power supply 1 according to a second embodiment of the present disclosure. The switching power supply 1 according to the second embodiment has the same basic configuration as that according to the first embodiment, but is equipped with an automatic slew-rate switching function. The same elements in the second embodiment as those in the first embodiment are denoted by the same reference numerals as in FIG. 1 and detailed explanations thereof are omitted.

A slew rate adjusting unit 15 is configured to control a current capacity (i.e., ability of driving) of a switch driving unit 12 based on a register value SWSRT (1:0) for adjusting a slew rate and a register value SWCHG (2:0) for setting a change pattern, which are to be read from a register unit 17. The switch driving unit 12 may be configured and controlled in the same manner as described above with respect to the first embodiment (e.g., the method of switching the number of unit drivers being operated simultaneously among a plurality of unit drivers), or in other manners (e.g., a method of selectively operating a plurality of drivers having different current capacities).

An interface unit 16 is configured to exchange signals with the outside of the switch control IC 100 (i.e., an external unit) via a communication terminal T₄. Specifically, in the second embodiment, the interface unit 16 exchanges a serial clock signal SCL and a serial data signal SDA with an I2C (Inter-Integrated Circuit) bus (not shown) provided outside the switch control IC 100.

The register unit 17 is configured to store various register values that are inputted through the interface unit 16 (for example, the above-mentioned register values SWSRT and SWCHG).

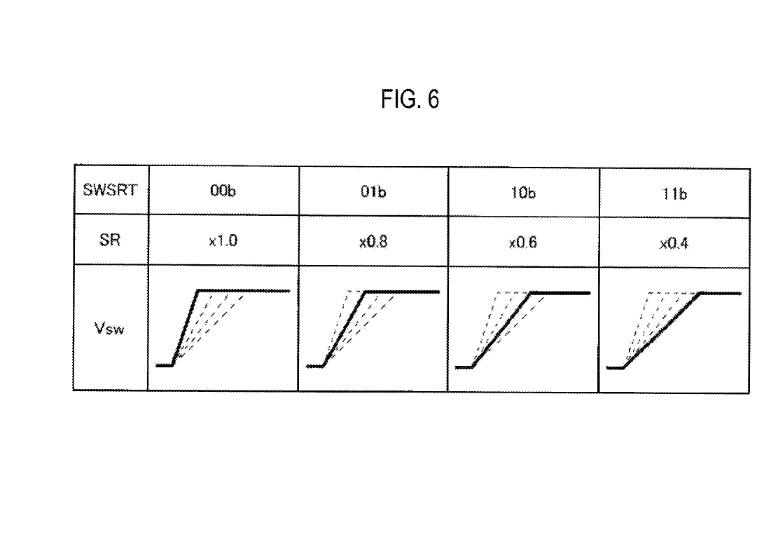

FIG. 6 illustrates examples of a slew-rate adjustment operation based on the register value SWSRT, in which the register value SWSRT, a slew rate SR of the output transistor 11, and a switch voltage V_{sw} are depicted. When the register value SWCHG is assigned “000b,” the slew rate adjusting unit 15 sets the current capacity (i.e., ability of driving) of the switch driving unit 12 such that the slew rate SR of the output transistor 11 is of a fixed value corresponding to the register value SWSRT.

In more detail, when the register value SWSRT is assigned “00b,” the slew rate adjusting unit 15 sets (e.g., fixes) the current capacity of the switch driving unit 12 such that the slew rate SR of the output transistor 11 is of a value “×1.0.” When the register value SWSRT is assigned “01b,” the slew rate adjusting unit 15 sets the current capacity of the switch driving unit 12 such that the slew rate SR of the output transistor 11 is of a value “×0.8.” When the register value SWSRT is assigned “10b,” the slew rate adjusting unit 15 sets the current capacity of the switch driving unit 12 such that the slew rate SR of the output transistor 11 is of a value “×0.6.” When the register value SWSRT is assigned “11b,” the slew rate adjusting unit 15 sets the current capacity of the switch driving unit 12 such that the slew rate SR of the output transistor 11 is of a value “×0.4.”

As such, if the register value SWCHG is assigned “000b,” the resister value SWSRT affects the slew rate SR of the output transistor 11 such that the slew rate SR is switched within the four steps according to the resister value SWSRT. Accordingly, like the first embodiment, without requiring a change in design of the switch driving unit 12 and a PCB, a balance between an efficiency and an amount of noise of the switching power supply 1 can be optimized for each mounted set.

In addition, the slew rate adjusting unit 15 has a function to control the current capacity (i.e., ability of driving) of the switch driving unit 12 so that the slew rate SR of the output transistor 11 can be periodically changed in any change pattern which can be switched based on the register value SWCHG.

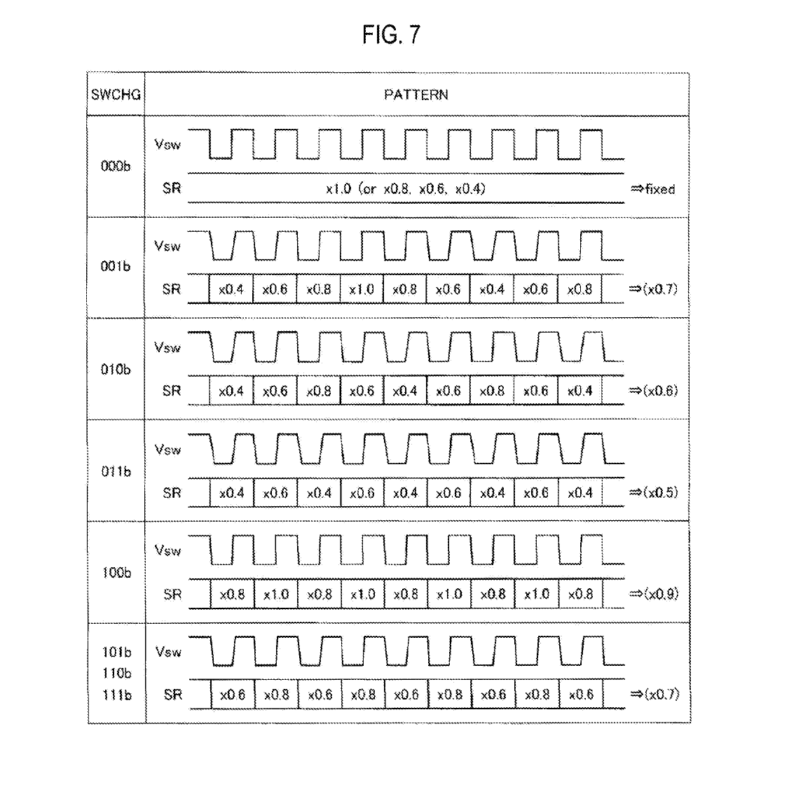

FIG. 7 illustrates examples of automatic slew-rate switching operations based on the register value SWCHG, in which mapping of the register value SWCHG to a change pattern of the slew rate SR is depicted.

When the register value SWCHG is assigned “000b,” the slew rate adjusting unit 15 sets the current capacity of the switch driving unit 12 such that the slew rate SR of the output transistor 11 is of a fixed value (“×1.0,” “×0.8,” “×0.6,” or “×0.4”) based on the register value SWSRT, as described above. Accordingly, a switching example of a change pattern may include the case where the slew rate SR of the output transistor 11 is set as a fixed value, and thus, it is possible to properly switch enabling/disabling of the automatic switching function of the slew rate SR.

When the register value SWCHG is assigned “001b,” the slew rate adjusting unit 15 controls the current capacity of the switch driving unit 12 such that the slew rate SR of the output transistor 11 changes according to a first change pattern for every ON/OFF period. The first change pattern includes four values (e.g., “×1.0,” “×0.8,” “×0.6,” and “×0.4”) as candidate values of the slew rate SR and the slew rate SR of the output transistor 11 is periodically switched, for example, in the order of “×0.4”→“×0.6”→“×0.8”→“×1.0”→“×0.8”→“×0.6”→“×0.4”→ . . . . As such, the slew rate adjusting unit 15 controls the current capacity of the switch driving unit 12 such that the slew rate SR of the output transistor 11 changes to increase and decrease between the maximum candidate value “×1.0” and the minimum candidate value “×0.4.” In this case, a time-average value of the slew rate SR (i.e., an apparent average value of the slew rate SR per unit time) is “×0.7.”

In addition, a method of repeating increasing the slew rate SR from “×0.4” to “×1.0” and then decreasing the slew rate to “×0.4” as a switching order of the slew rate SR, such as “×0.4”→“×0.6”→“×0.8”→“×1.0”→“×0.4”→“×0.6”→“×0.8”→ . . . (or vice versa), may be employed. However, this switching method may provide a switching operation having low stability since the slew rate SR periodically changes drastically (e.g., “×1.0”→“×0.4”).

On the other hand, as described above, the switching method of increasing and decreasing the slew rate between the maximum candidate value and the minimum candidate value does not impair the stability of the switching operation since a variation occurring in the automatic switching of the slew rate SR can be minimized.

When the register value SWCHG is assigned “010b,” the slew rate adjusting unit 15 may control the current capacity of the switch driving unit 12 such that the slew rate SR of the output transistor 11 changes according to a second change pattern for every ON/OFF period. The second change pattern includes three values (e.g., “×0.8,” “×0.6,” and “×0.4”) as candidate values of the slew rate SR and the slew rate SR of the output transistor 11 is periodically switched in the order of “×0.4”→“×0.6”→“×0.8”→“×0.6”→“×0.4”→ . . . . As such, like the first change pattern, the slew rate adjusting unit 15 controls the current capacity of the switch driving unit 12 such that the slew rate SR of the output transistor 11 changes to increase and decrease between the maximum candidate value “×0.8” and the minimum candidate value “×0.4.” In this case, a time-average value of the slew rate SR is “×0.6.” Thus, setting the change pattern to match the time-average value of the slew rate SR to one of the fixed values may be possible.

When the register value SWCHG is assigned “011b,” the slew rate adjusting unit 15 controls the current capacity of the switch driving unit 12 such that the slew rate SR of the output transistor 11 changes according to a third change pattern for every ON/OFF period. The third change pattern includes two values (e.g., “×0.6” and “×0.4”) as candidate values of the slew rate SR and the slew rate SR of the output transistor 11 is periodically switched in the order of “×0.4”→“×0.6”→“×0.4”→“×0.6”→ . . . . In this case, a time-average value of the slew rate SR is “×0.5.”

When the register value SWCHG is assigned “100b,” the slew rate adjusting unit 15 controls the current capacity of the switch driving unit 12 such that the slew rate SR of the output transistor 11 changes according to a fourth change pattern for every ON/OFF period. The fourth change pattern includes two values (i.e., “×1.0” and “×0.8”) as candidate values of the slew rate SR and the slew rate SR of the output transistor 11 is periodically switched in an order of “×0.8”→“×1.0”→“×0.8”→“×1.0”→ . . . . In this case, a time-average value of the slew rate SR is “×0.9”.

If the register value SWCHG is assigned “101b”, “110b,” or “111b”, the slew rate adjusting unit 15 controls the current capacity of the switch driving unit 12 so that the slew rate SR of the output transistor 11 changes according to a fifth change pattern for every ON/OFF period. The fifth change pattern includes two values, i.e., “×0.8” and “×0.6” as candidate values of the slew rate SR and the slew rate SR of the output transistor 11 is periodically switched in the order of “×0.6”→“×0.8”→“×0.6”→“×0.8”→ . . . . In this case, a time-average value of the slew rate SR is “×0.7.” Thus, setting the change patterns to match the time-average values of the slew rate SR to each other may be possible.

As described above, with the automatic slew rate switching operation based on the register value SWCHG, it is possible to properly set the slew rate SR of the output transistor 11 to not only one of the fixed values (“×1.0”, “×0.8”, “×0.6” and “×0.4”) and but also an intermediate value thereof

Although FIG. 7 illustrates change patterns in which the slew rate SR is switched every one cycle, the slew rate SR may be switched every two or more cycles. In addition, different weights may be assigned to different candidate values of the slew rate SR. For example, when “×0.8” and “×1.0” are switched with a ratio of 2:1, a time-average value is “×0.87.” If “×0.8” and “×1.0” are switched with a ratio of 1:2, a time-average value is “×0.93.” Thus, when different weights are assigned to different candidate values of the slew rate SR, it is possible to finely adjust a time average value of the slew rate SR.

### <Electronic Apparatuses>

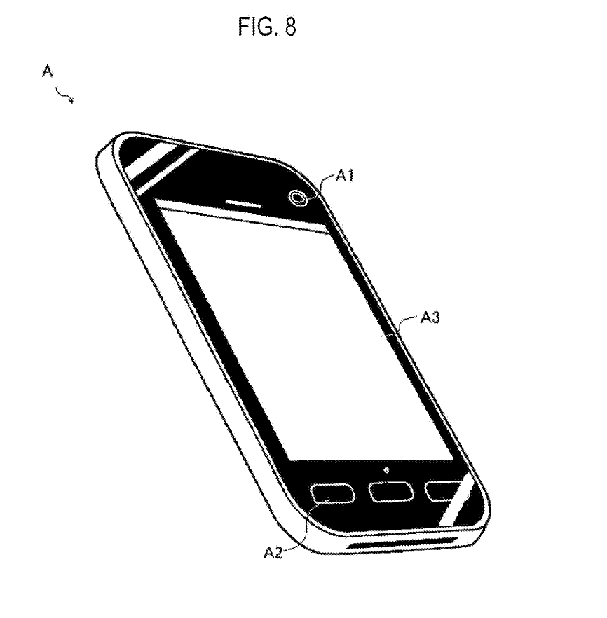

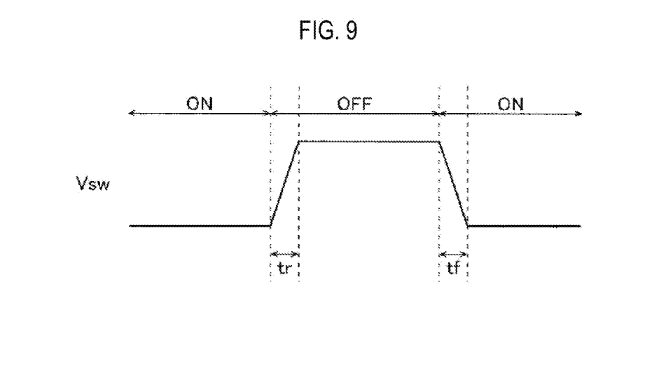

FIG. 8 illustrates an external appearance of a mobile phone (e.g., a smartphone). A mobile phone A is an example of an electronic apparatus including the above-described switching power supply 1. As shown, the mobile phone A includes an imaging unit Aₗ mounted on a front or back of a body, an operating unit A₂ (e.g., various buttons, etc.) for receiving instructions from a user, and a display unit A₃ for displaying characters and images. The display unit A₃ may have a touch panel function to sense touches by the user.

The above-described switching power supply 1 may be installed as a power supply in the mobile phone A, thereby allowing extension of battery life without increasing noise.

### <Other Modifications>

Although the boost switching power supply has been illustrated in the above embodiments, the present disclosure is not limited thereto but may be applied to other power supplies including a step-down switching supply or a step-up switching power supply.

The switch control circuit of the present disclosure may be appropriately incorporated in a motor driver, a LED (Light Emitting Diode) driver and so on in addition to the switching power supply.

The switching power supply disclosed herein may be used as a power supply for various electronic apparatuses including a mobile phone (e.g., a smartphone).

According to the present disclosure in some embodiments, it is possible to provide a switch control circuit which is capable of optimizing a balance between efficiency and an amount of noise for each mounted set, a switching power supply including the switch control circuit, and an electronic apparatus including the switching power supply.

While certain embodiments have been described, these embodiments have been presented by way of example only, and are not intended to limit the scope of the disclosure. Indeed, the novel methods and apparatuses described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A switch control circuit comprising:
a control unit configured to generate a control signal;
a switch driving unit configured to drive a switch element based on the control signal; and
a slew rate adjusting unit configured to control the switch driving unit to change a slew rate of the switch element periodically in a predetermined change pattern.

2. The switch control circuit of claim 1, wherein the slew rate adjusting unit is further configured to control the switch driving unit to increase and decrease the slew rate of the switch element between a maximum candidate value and a minimum candidate value in the change pattern.

3. The switch control circuit of claim 1, wherein the slew rate adjusting unit is further configured to control the switch driving unit to change the slew rate of the switch element every period of the control signal.

4. The switch control circuit of claim 1, further comprising:
an interface unit configured to exchange a signal with an external unit; and
a register configured to store a plurality of register values that are inputted through the interface unit,
wherein the slew rate adjusting unit is further configured to switch the change pattern based on a register value associated with change pattern setting.

5. The switch control circuit of claim 4, wherein the change pattern includes setting the slew rate of the switch element to be a fixed value.

6. The switch control circuit of claim 5, wherein the fixed value is associated with a register value associated with a slew rate adjustment.

7. The switch control circuit of claim 1, wherein the switch driving unit includes a plurality of unit drivers connected in parallel, and
wherein the slew rate adjusting unit changes periodically a number of unit drivers being operated simultaneously among the plurality of unit drivers.

8. The switch control circuit of claim 7, wherein the plurality of unit drivers is formed by transistors having the same size.

9. A switching power supply comprising:
the switch control circuit of claim 1; and
an output stage configured to generate an output voltage from an input voltage based on control by the switch element according to the switch control circuit.

10. An electronic apparatus comprising:
the switching power supply of claim 9; and
a load which is supplied with the output voltage from the switching power supply.
